(19) United States
(12) Patent Application Publication
(10) Pub. No.: US 2022/0278669 A1
(43) Pub. Date: Sep. 1, 2022

(54) TWO-DIMENSIONAL HIGH-PERFORMANCE RESONATOR

(71) Applicant: Ningbo Huazhang Enterprise Management Partnership (Limited Partnership), Ningbo (CN)

(72) Inventors: Chengliang SUN, Wuhan (CN); Jieyu LIU, Wuhan (CN); Jie ZHOU, Wuhan (CN); Xin TONG, Wuhan (CN); Chao GAO, Wuhan (CN); Yang ZOU, Wuhan (CN)

(21) Appl. No.: 17/746,954

(22) Filed: May 17, 2022

Related U.S. Application Data
(63) Continuation-in-part of application No. PCT/CN2020/111348, filed on Aug. 26, 2020.

(30) Foreign Application Priority Data
Nov. 18, 2019 (CN) 201911127186.6
Dec. 30, 2019 (CN) 201911398316.X

(51) Int. Cl. H03H 9/13; H03H 9/02; H03H 9/17

(52) U.S. Cl. CPC H03H 9/132; H03H 9/02031; H03H 9/02228; H03H 9/176

(57) ABSTRACT

The disclosure discloses a two-dimensional high-performance resonator, which is specifically an ultra-high-frequency resonator structure capable of improving an electromechanical coupling coefficient of the resonator. The resonator includes a piezoelectric layer, where an electrode layer is distributed on the upper surface of the piezoelectric layer, the electrode layer includes a plurality of electrodes arranged in a horizontal direction with a distance therebetween greater than four wavelengths, and a bridge structure is arranged on an upper portion of the electrode layer. The resonator structure can effectively improve the resonance frequency and the electromechanical coupling coefficient of the resonator, and can meet the requirements of the 5G market, and the quality factor is greatly improved.

### CROSS-REFERENCE TO RELAYED APPLICATIONS

This application is a continuation-in-part of International Patent Application No. PCT/CN2020/111348 with an international filing date of Aug. 26, 2020, designating the United States, now pending, and further claims foreign priority benefits to Chinese Patent Application No. 201911127186.6 filed Nov. 18, 2019, and to Chinese Patent Application No. 201911398316.X filed Dec. 30, 2019. The contents of all of the aforementioned applications, including any intervening amendments thereto, are incorporated herein by reference. Inquiries from the public to applicants or assignees concerning this document or the related applications should be directed to: Matthias Scholl P C., Attn.: Dr. Matthias Scholl Esq., 245 First Street, 18th Floor, Cambridge, Mass. 02142.

### BACKGROUND

The disclosure relates to the field of resonators, and more particularly, to a two-dimensional high-performance resonator.

Surface acoustic wave (SAW) resonators are widely applied to a radio frequency front end in an early stage, but are difficult to maintain the excellent performance in high bands due to a low phase velocity, a limitation on lithography, and the like. Bulk acoustic wave (BAW) resonators are widely applied to the high-frequency resonator field due to low insertion loss and a good power capability. Among them, film bulk acoustic resonators (FBARs) particularly have a high quality factor (Q) and a high electromechanical coupling coefficient (K2). However, the resonance frequency of the FBAR is determined by the thickness of the piezoelectric film, making it difficult to achieve multi-band integration on a single wafer. The proposal of the Lamb wave resonator (LWR) can break through the frequency limitation of the SAW resonator. Lamb wave resonators with different frequencies can be obtained by adjusting an interdigital distance, to achieve frequency modulation of the same wafer.

A conventional one-dimensional Lamb wave resonator is of a sandwich structure. Top and bottom electrodes adopt an interdigital transducer structure, and the middle is a piezoelectric material layer. The distance between the adjacent interdigital transducer is generally one wavelength, and a zero-order symmetrical mode is laterally excited. The vibration of a two-dimensional Lamb wave resonator is the coupling of the lateral excitation and the thickness direction excitation, and the characteristic can improve an electromechanical coupling coefficient and a quality factor of the Lamb wave resonator to a certain extent. However, the complex structure and the relatively low quality factor and electromechanical coupling coefficient of the Lamb wave resonator are the main reasons that limit the commercialization of the Lamb wave resonator.

Mobile phones rely on miniaturized high-performance radio frequency (RF) filters to implement their increasingly complex architectures, and new 5G standards require higher frequency and larger bandwidth. The higher demands require high frequencies greater than 3 GHz and a wide band greater than 10%. This poses serious challenges for existing lithium niobate (LiTaO₃)/lithium tantalate (LiNbO₃)-based surface acoustic wave (SAW) and AlN-based bulk acoustic wave (BAW) technologies, which are generally limited by lower electromechanical coupling, around 3% bandwidth, and the increasingly small dimensional requirements for high frequencies. Low temperature co-fired ceramic (LTCC) filters can support wide bands, but require larger form factors, have higher losses, and lack steep suppression required for high quality factor (Q) acoustic resonators.

To meet this requirement, laterally-excited shear-mode bulk acoustic wave resonators (XBARs) that have low losses, and a relative bandwidth of 11% at 4.8 GHz are recently proposed. The XBAR has a relatively simple structure, including a metallized interdigital electrode (IDE) system, but with a small metallization ratio. The electrodes mainly generate horizontal electric fields, which generate a half-wavelength bulk shear wave Al resonance in a suspended LiNbO₃ film. A maximum acoustic amplitude is located in the free film area between two electrodes. The design trade-offs are quite different from conventional micro-acoustic resonators. In the surface acoustic wave device, the distance between metal interdigital transducer (IDT) electrodes is closely related to the resonator frequency, and in the surface acoustic wave resonator and the bulk acoustic wave resonator, the metal thickness greatly affects the resonator frequency and the quality factor. The frequency of the XBAR is mainly determined by the thickness of the piezoelectric plate.

Currently, it is difficult for the existing XBAR structure to completely eliminate the impact of the spurious mode, and the electromechanical coupling coefficient needs to be sacrificed a considerable extent to obtain a high quality factor.

### SUMMARY

An objective of the disclosure is to provide an ultra-high-frequency and high-performance resonator capable of improving the electromechanical coupling coefficient and the quality factor of the resonator and reducing the spurious modes.

To achieve the foregoing objective, the disclosure provides a two-dimensional high-performance resonator, comprising a piezoelectric layer, wherein an electrode layer is distributed on an upper surface of the piezoelectric layer; the electrode layer comprises a plurality of electrodes arranged in a horizontal direction with respect to xy-plane with a distance therebetween greater than four wavelengths, and a bridge structure is arranged on an upper portion of the electrode layer.

In a class of this embodiment, the bridge structure is in direct contact with the piezoelectric layer and connects electrodes that are adjacent in a vertical direction.

In a class of this embodiment, the bridge structure is in indirect contact with the piezoelectric layer and connects electrodes that are adjacent in a vertical direction with respect to xy-plane.

In a class of this embodiment, a shape of the bridge structure is a rectangle, a quadrangle, or a polygon.

In a class of this embodiment, a material of the bridge structure is selected from platinum, molybdenum, gold, tungsten, copper, or aluminum.

In a class of this embodiment, a material of the piezoelectric layer is selected from lithium niobate, lithium tantalate, aluminum nitride, or doped aluminum nitride.

In a class of this embodiment, a material of the electrode is selected from platinum, molybdenum, gold, tungsten, copper, or aluminum.

In a class of this embodiment, the electrode layer comprises a plurality of electrodes arranged in a vertical direction with a distance therebetween less than and equal to four wavelengths.

In a class of this embodiment, a shape of the electrode is an ellipse, a circle, a rectangle, a rhombus, a hexagon, an octagon, a polygon, or a combination of different shapes.

In a class of this embodiment, the shape of the electrode is an ellipse, the distance between adjacent electrodes distributed in the horizontal direction is greater than four wavelengths, and the distance between adjacent electrodes distributed in the vertical direction is less than four wavelengths and twice a major axis of the ellipse.

In a class of this embodiment, the shape of the electrode is an ellipse, the distance between adjacent electrodes distributed in the horizontal direction is greater than four wavelengths, and the distance between adjacent electrodes distributed in the vertical direction is less than four wavelengths and greater than twice a major axis of the ellipse.

In a class of this embodiment, the two-dimensional electrode arrangement of the two-dimensional high-performance resonator enables an electric field in the horizontal direction and a vertical direction to generate a coupling effect, and coupling of the multi-directional electric field increases an electromechanical coupling coefficient of the resonator.

The disclosure has the following beneficial effects:

Compared with a conventional existing resonator structure, the disclosure has the following advantages: The disclosure can achieve a high resonance frequency, and has a high electromechanical coupling coefficient at the high resonance frequency, and the ultra-high frequency and the high electromechanical coupling coefficient determine the performance of a subsequently built filter. The feasible structure of the disclosure means that 5 GHz can be broken through, and a chip with a higher frequency and higher performance is implemented. The ultra-high-frequency high-performance resonator structure based on specifically arranged electrodes can achieve a resonance frequency of 6 GHz and can better meet the requirements of the 5G market. In addition, in the disclosure, the resonator structure with an elliptical electrode can achieve an ultra-high electromechanical coupling coefficient greater than 40%, and the quality factor is also greatly improved.

### BRIEF DESCRIPTION OF THE DRAWINGS

FIG. 1 is a conventional one-dimensional aluminum nitride film based Lamb wave resonator structure;

FIG. 2 is a conventional two-dimensional Lamb wave resonator structure;

FIG. 3 is a two-dimensional resonator structure with circular electrodes as an example according to Embodiment 1 of the disclosure;

FIG. 4 is a schematic structural diagram of a two-dimensional resonator with hexagonal electrodes as an example according to Embodiment 2 of the disclosure;

FIG. 5 is a main view of the two-dimensional resonator with hexagonal electrodes as an example according to Embodiment 2 of the disclosure;

FIG. 6 is a schematic structural diagram of a resonator with circular electrodes linearly arranged in a two-dimensional manner as an example according to Embodiment 3 of the disclosure;

FIG. 7 is a schematic structural diagram of a two-dimensional high-performance resonator with elliptical electrodes as an example according to Embodiment 4 of the disclosure;

FIG. 8 is a schematic structural diagram of a two-dimensional high-performance resonator with elliptical electrodes as an example according to Embodiment 5 of the disclosure;

FIG. 9 is an electrode distribution diagram of a two-dimensional high-performance resonator structure with elliptical electrodes as an example according to Embodiment 6 of the disclosure;

FIG. 10 is an electrode distribution diagram of a two-dimensional high-performance resonator structure with elliptical electrodes as an example according to Embodiment 7 of the disclosure;

FIGS. 11A-11B are two schematic distribution diagrams of a bridge structure in a two-dimensional high-performance resonator according to Embodiment 8 of the disclosure;

FIGS. 12A-12B are the amplitude diagrams of the two-dimensional resonator with circular electrodes according to Embodiment 1 of the disclosure and an amplitude diagram of a conventional Lamb wave resonator;

FIG. 13 is a schematic diagram of an impedance curve of the two-dimensional resonator with hexagonal electrodes according to Embodiment 2 of the disclosure and an impedance curve of a conventional Lamb wave resonator;

FIG. 14 is a schematic diagram of an impedance curve of the two-dimensional resonator with elliptical electrodes according to Embodiment 3 of the disclosure and an impedance curve of the two-dimensional resonator with circular electrodes according to Embodiment 1 of the disclosure; and

FIG. 15 is a schematic diagram of an impedance curve of the two-dimensional resonator with elliptical electrodes according to Embodiment 3 of the disclosure, an impedance curve of the two-dimensional resonator with circular electrodes according to Embodiment 1 of the disclosure, and an impedance curve of a conventional Lamb wave resonator.

In the figures: 1. Piezoelectric layer, 3. First electrode, 4. Second electrode, 5. First electrode layer, 6. Second electrode layer, and 7. Bridge structure.

### DETAILED DESCRIPTION

The technical solutions of embodiments of the disclosure are clearly and completely described below with reference to the accompanying drawings in the embodiments of the disclosure. Obviously, the described embodiments are merely a part rather than all of the embodiments of the disclosure. All other embodiments obtained by a person of ordinary skill in the art based on the embodiments of the disclosure without creative efforts shall fall within the protection scope of the disclosure.

In the description of the disclosure, it should be understood that orientation or position relationships indicated by the terms such as “center”, “above”, “below”, “left”, “right”, “vertical”, “horizontal”, “inside”, and “outside” are based on orientation or position relationships shown in the accompanying drawings, and are used only for ease and brevity of illustration and description of the disclosure, rather than indicating or implying that the mentioned apparatus or component must have a particular orientation or must be constructed and operated in a particular orientation. Therefore, such terms should not be construed as limiting of the disclosure. In addition, the terms “first” and “second” are used for descriptive purposes only and are not to be construed as indicating or implying relative importance or implicitly indicating the number of technical features indicated. Therefore, features defining “first” and “second” may explicitly or implicitly include one or more such features. In creative descriptions of the disclosure, “a plurality of” means two or more, unless otherwise stated.

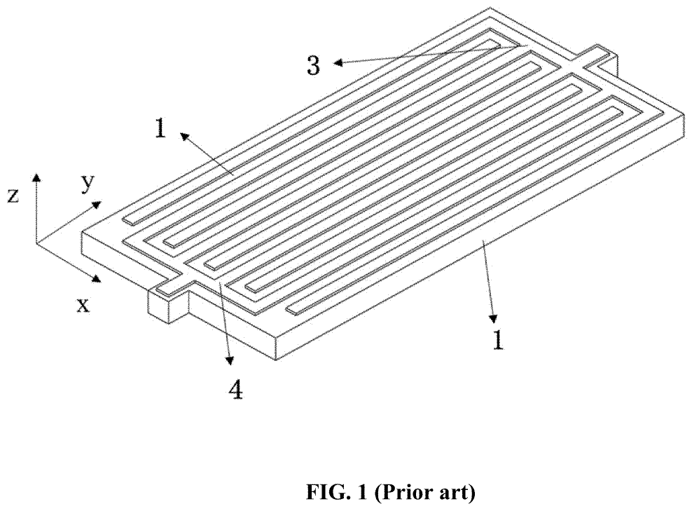

FIG. 1 is a schematic structural diagram of a conventional one-dimensional aluminum nitride film based Lamb wave resonator. As shown in the figure, interdigital electrode layers are arranged on an upper surface and a lower surface of a piezoelectric layer 1. Electrodes on the electrode layer are divided into two groups, which are respectively first electrodes 3 and second electrodes 4. A positive voltage is applied to one group, and a negative voltage is applied to the other group. When a distance between interdigital electrodes and a thickness of the piezoelectric layer 1 are in the same order of magnitude, a Lamb wave propagated in an x-axis direction is excited inside the piezoelectric layer 1.

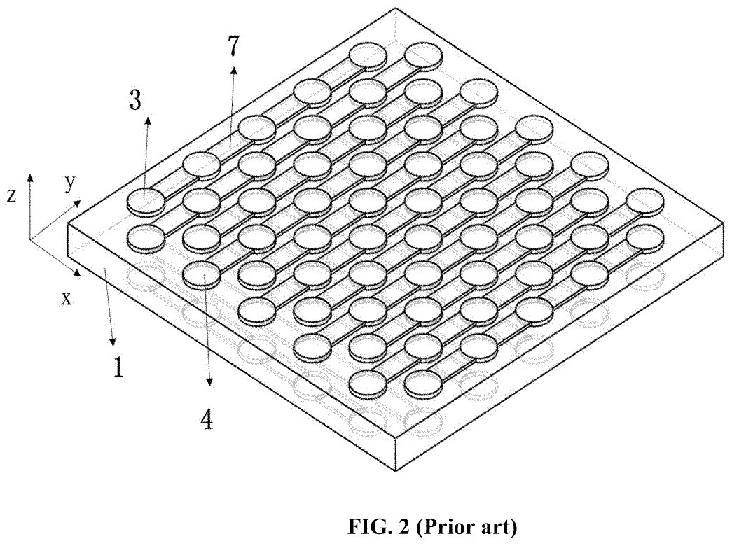

FIG. 2 is a schematic structural diagram of a conventional two-dimensional Lamb wave resonator. As shown in the figure, electrode layers are uniformly arranged on an upper surface and a lower surface of a piezoelectric layer 1. Electrodes on the electrode layers are divided into two groups, which are respectively first electrodes 3 and second electrodes 4. A positive voltage is applied to one group, and a negative voltage is applied to the other group. As shown in the figure, both the first electrodes 3 and the second electrodes 4 are circular. The first electrodes 3 and the second electrodes 4 are respectively distributed on the upper surface and the lower surface of the piezoelectric layer 1, so that alternating current voltages may be applied to the upper surface and the lower surface of the piezoelectric layer 1. The electrode layers are connected by using a bridge structure 7. The bridge structure 7 may be in contact with the surface of the piezoelectric layer 1 or may not be in contact with the surface of the piezoelectric layer 1. If bridges on the upper surface are arranged in parallel in a y-axis, bridges on the lower surface are arranged in an x-axis. In addition, if a positive voltage is applied to the first electrode 3 on the upper surface, the second electrode 4 on the lower surface right opposite to the first electrode 3 on the upper surface is negatively charged. This structure excites transverse waves transmitted in the x-axis and the y-axis and a longitudinal wave transmitted in a z-axis, to generate two-dimensional Lamb waves. By using the Lamb waves transmitted in two directions, this structure not only eliminates an adverse effect of parasitic modes but also enhances electrical reflection of a main mode by using a wave of the parasitic mode, to improve an electromechanical coupling coefficient.

### Embodiment 1

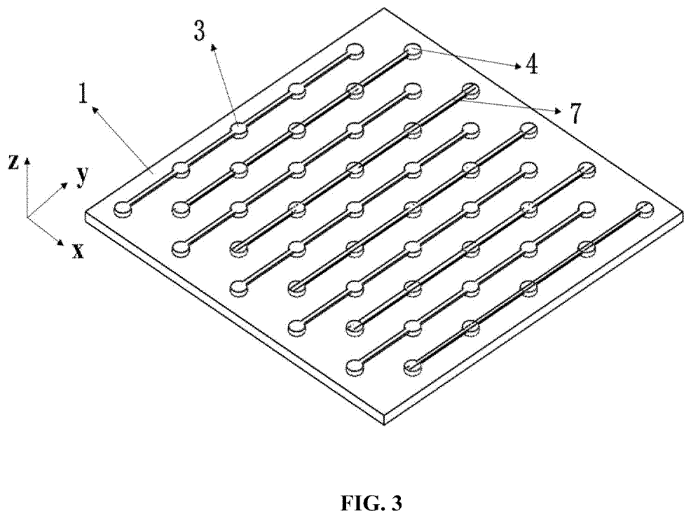

FIG. 3 is a schematic structural diagram of a two-dimensional resonator according to Embodiment 1 of the disclosure. As shown in the figure, an electrode layer is arranged on an upper surface of a piezoelectric layer 1. Electrodes on the electrode layer are divided into two groups, one group is referred to as first electrodes 3, and the other group is referred to as second electrodes 4. The first electrodes 3 distributed in a y-axis direction are connected by using a bridge structure 7, and the first electrodes 3 connected by using the bridge structure form a first electrode layer 5. The second electrodes 4 distributed in the y-axis direction are connected by using a bridge structure 7, and the second electrodes 4 connected by using the bridge structure form a second electrode layer 6. The first electrode layer 5 and the second electrode layer 6 are alternately arranged, and voltages of different polarities are respectively applied to the first electrode layer 5 and the second electrode layer 6 that are adjacent. If a positive voltage is applied to the first electrode layer 5, a negative voltage is applied to the second electrode layer 6. If a negative voltage is applied to the first electrode layer 5, a positive voltage is applied to the second electrode layer 6. A distance between the first electrode layer 5 distributed in the x-axis direction and its adjacent second electrode layer 6 is greater than four wavelengths, and an end portion of the first electrode layer 5 and an end portion of the second electrode layer 6 are not on the same horizontal line. A transverse electric field is generated between the first electrode layer 5 and the second electrode layer 6 that have different voltages, and an acoustic wave is excited, to implement conversion between electric energy and mechanical energy. Compared with the conventional two-dimensional Lamb wave resonator shown in FIG. 2, in the disclosure, the electrode layer needs to be arranged on only the upper surface of the piezoelectric layer 1 without the need of being arranged on the lower surface of the piezoelectric layer 1. However, compared with the conventional two-dimensional Lamb wave resonator, the disclosure can achieve a higher frequency and has a higher electromechanical coupling coefficient.

A shape of the bridge structure is a rectangle, a quadrangle, or a polygon. The selection of the shape of the bridge structure can be changed adaptively according to the arrangement and shape of the electrode, to meet the requirements of connecting various electrodes, and a spurious mode of the resonator can be well suppressed after the bridge structure is arranged.

A material of the bridge structure is selected from platinum, molybdenum, gold, tungsten, copper, or aluminum.

A material of the piezoelectric layer 1 is selected from lithium niobate, lithium tantalate, aluminum nitride, or doped aluminum nitride. Lithium niobate and lithium tantalate are new generation piezoelectric film materials and are applicable to a high-frequency device. Lithium niobate has a large piezoelectric coefficient and is applicable to a large bandwidth piezoelectric device. Lithium tantalate has a relatively small piezoelectric coefficient and is applicable to a narrowband piezoelectric device. Aluminum nitride is a conventional piezoelectric film material and has the advantages of high quality factor, low loss, high acoustic velocity, low cost, excellent temperature performance, and integration and compatibility with a complementary metal oxide semiconductor (CMOS) process. Doped aluminum nitride improves the bandwidth compared with aluminum nitride.

A material of the electrode is selected from platinum, molybdenum, gold, tungsten, copper, or aluminum.

### Embodiment 2

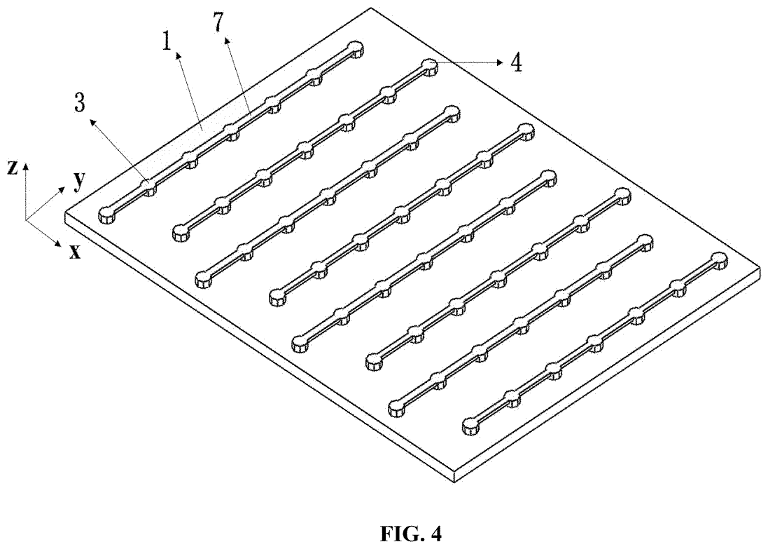

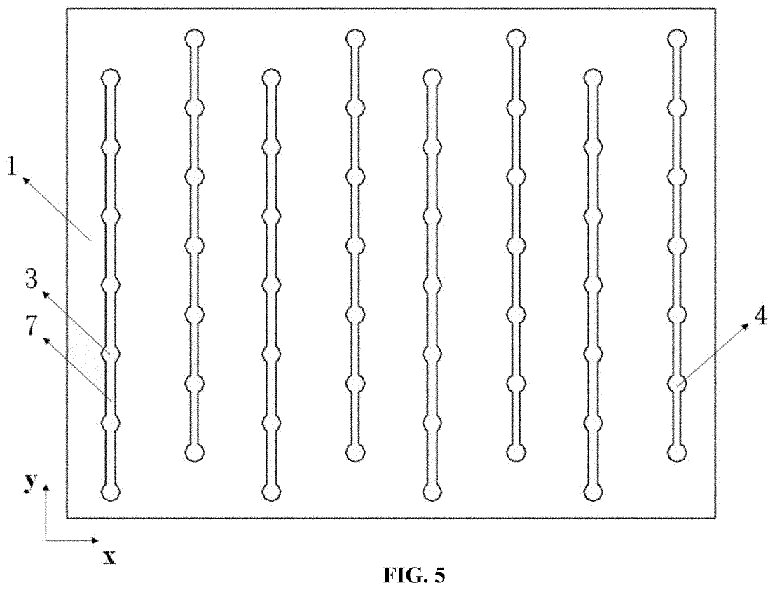

FIG. 4 is a schematic structural diagram of a two-dimensional resonator with hexagonal electrodes according to Embodiment 2 of the disclosure. FIG. 5 is a main view of the two-dimensional resonator structure with hexagonal electrodes according to Embodiment 2 of the disclosure. Shapes of the first electrode 3 and the second electrode 4 of the electrode layer are hexagons, and the remaining structure is the same as that in Embodiment 1. Compared with Embodiment 1, the advantage of this embodiment is that the pseudo mode of the resonator can be suppressed to a certain extent, and the performance of the resonator can be improved.

### Embodiment 3

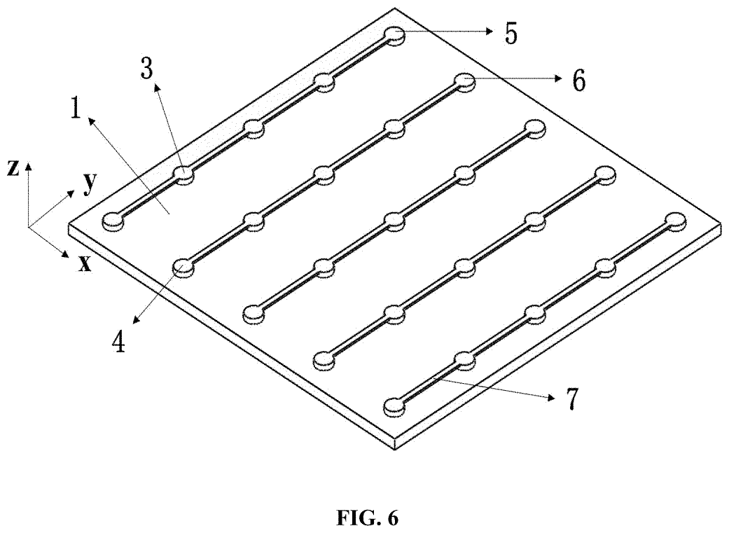

FIG. 6 is a schematic structural diagram of a resonator with circular electrodes linearly arranged in a two-dimensional manner according to Embodiment 3 of the disclosure. The end portion of the first electrode layer 5 and the end portion of the second electrode layer 6 are on the same horizontal line, and the remaining structure is the same as that in Embodiment 1. Compared with Embodiment 1, the advantage of this embodiment is that a coupled electric field excited inside the piezoelectric layer 1 is more regular.

### Embodiment 4

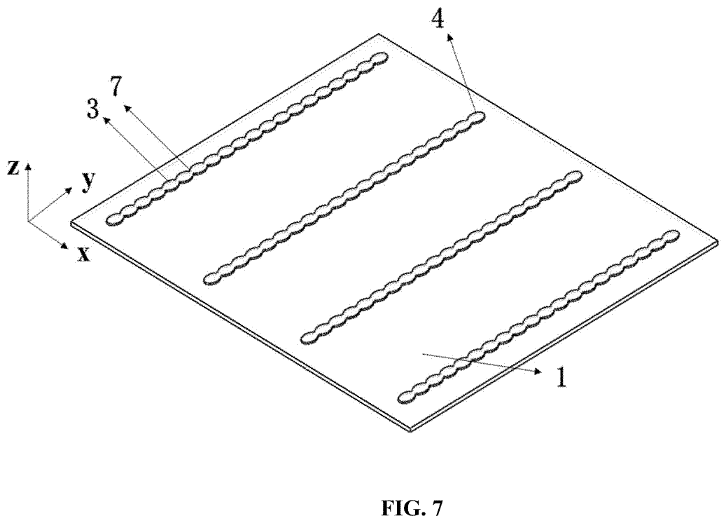

FIG. 7 is a schematic structural diagram of a two-dimensional high-performance resonator with elliptical electrodes as an example according to Embodiment 4 of the disclosure. An electrode layer is distributed on an upper surface of a piezoelectric layer 1 on a two-dimensional xy plane, and has elliptical electrodes. The electrodes on the electrode layer are divided into two groups, one group is referred to as first electrodes 3, and the other group is referred to as second electrodes 4. The first electrodes 3 distributed in a y-axis direction are in contact with each other and are connected by using a bridge structure 7, and the first electrodes 3 connected by using the bridge structure form a first electrode layer 5. The second electrodes 4 distributed in the y-axis direction are in contact with each other and are connected by using a bridge structure 7, and the second electrodes 4 connected by using the bridge structure form a second electrode layer 6. The first electrode layer 5 and the second electrode layer 6 are alternately arranged, and voltages of different polarities are respectively applied to the first electrode layer 5 and the second electrode layer 6 that are adjacent. A distance between the first electrode layer 5 distributed in the x-axis direction and its adjacent second electrode layer 6 is greater than four wavelengths. When a distance between the first electrode 3 and the second electrode 4 in the x-axis direction and a thickness of the piezoelectric layer 1 are in the same order of magnitude, a Lamb wave propagated in the x-axis direction may be excited inside the piezoelectric layer 1. A propagation equation of the Lamb wave in the piezoelectric layer is: f=v/λ, where f is a frequency of the resonator, V is a phase velocity of acoustic wave propagation, and λ is an acoustic wavelength. When the distance between the first electrode 3 and the second electrode 4 in the x-axis direction is adjusted, another wave for example, a transverse shear wave, may be excited. Voltages of the same polarity are applied to electrodes in the y-axis direction, and a distance between the electrodes needs to be less than four wavelengths. As the distance gradually decreases, an impedance curve of the resonator is smoother, and the performance of the resonator is better. As shown in FIG. 7, adjacent electrodes in the y-axis direction are in direct contact, to conduct a current in the direction.

### Embodiment 5

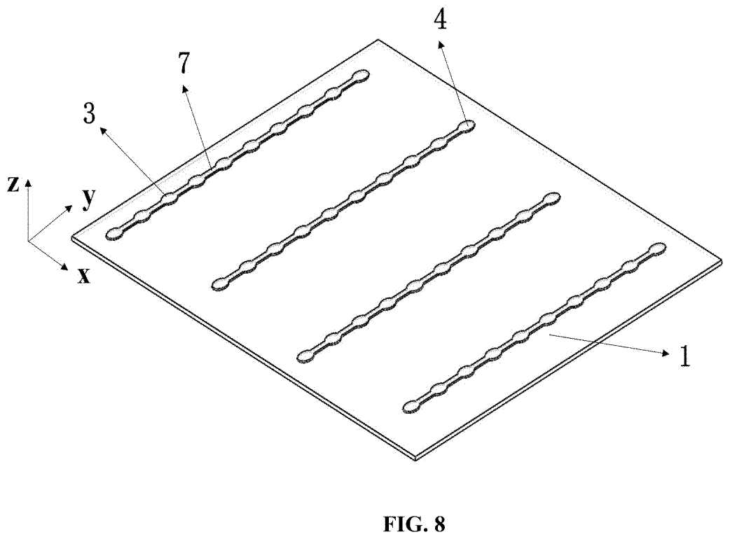

FIG. 8 is a schematic structural diagram of a two-dimensional high-performance resonator with elliptical electrodes as an example according to Embodiment 5 of the disclosure. Similar to FIG. 7, an electrode layer distributed in a two-dimensional direction is arranged on an upper surface of a piezoelectric layer 1, and has elliptical electrodes. A material of the electrode layer may be a metal material such as molybdenum, aluminum, copper, or gold. First electrodes 3 distributed in a y-axis direction are in indirect contact with each other and are connected by using a bridge structure 7, and the first electrodes 3 connected by using the bridge structure form a first electrode layer 5. Second electrodes 4 distributed in the y-axis direction are in indirect contact with each other and are connected by using a bridge structure 7, and the second electrodes 4 connected by using the bridge structure form a second electrode layer 6. The first electrode layer 5 and the second electrode layer 6 are alternately arranged, and voltages of different polarities are respectively applied to the first electrode layer 5 and the second electrode layer 6 that are adjacent in an x-axis direction. Positive and negative alternating voltages are applied to the electrode layer in the x-axis direction. In this voltage applying manner, a bulk acoustic wave may be excited in the x-axis direction, to implement electrical-acoustic conversion. Electrodes distributed in the y-axis direction on the upper surface of the piezoelectric layer 1 are provided with voltages of the same polarity, and the electrodes in the direction are connected by using the bridge structure 7 shown in FIG. 2. The bridge structure 7 may be in direct or indirect contact with the piezoelectric layer 1. This structure excites transverse waves transmitted in an x axis and a y axis and a longitudinal wave transmitted in a z axis, to generate multi-dimensional bulk acoustic waves. By using the bulk acoustic waves transmitted in a plurality of directions, this structure not only eliminates an adverse effect of a parasitic mode but also enhances electrical reflection of a main mode by using a wave of the parasitic mode, to improve an electromechanical coupling coefficient.

### Embodiment 6

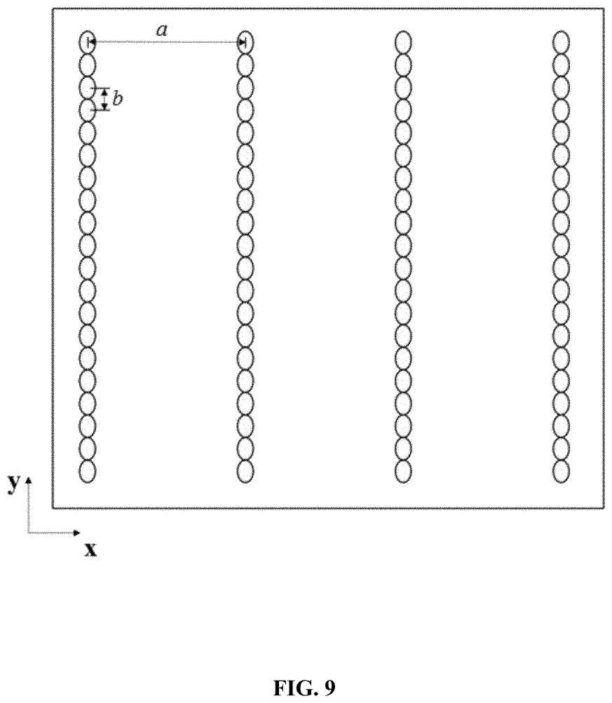

FIG. 9 is an electrode distribution diagram of a two-dimensional high-performance resonator structure with elliptical electrodes as an example according to Embodiment 6 of the disclosure. As shown in FIG. 9, a distance a between a first electrode 3 and a second electrode 4 that are adjacent and distributed in an x-axis direction and a distance b between electrodes in a y-axis direction are key factors affecting the performance of the resonator. The distance a between the first electrode 3 and the second electrode 4 that are adjacent and distributed in the x-axis direction designed in Embodiment 6 is greater than four wavelengths, and the distance b between the adjacent electrodes in the y-axis direction is less than four wavelengths. The electrode shown in FIG. 9 is an ellipse, and the distance b distributed in the y-axis direction is equal to double a major axis of the ellipse.

### Embodiment 7

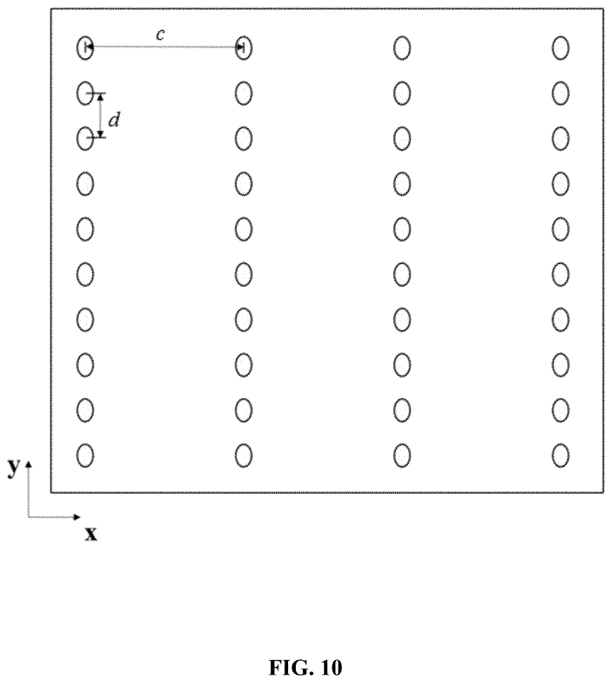

FIG. 10 is an electrode distribution diagram of a two-dimensional high-performance resonator structure with elliptical electrodes as an example according to Embodiment 7 of the disclosure. As shown in FIG. 10, the electrode is still an ellipse for example, or the electrode may be in the shape of a circle, a hexagon, a rhombus, or the like. The electrode distribution in Embodiment 7 is different from the electrode distribution structure in Embodiment 6, a distance c between a first electrode 3 and a second electrode 4 that are adjacent and distributed in an x-axis direction designed in Embodiment 7 is greater than four wavelengths, and a distance d between adjacent electrodes in a y-axis direction is greater than twice a major axis of the ellipse and less than four wavelengths.

### Embodiment 8

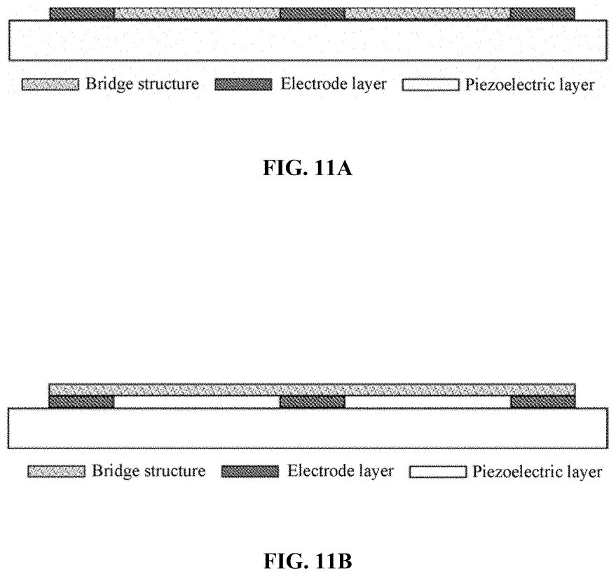

FIGS. 11A-11B are two schematic distribution diagrams of a bridge structure of a two-dimensional high-performance resonator. The resonator structure is formed by a piezoelectric layer 1, an electrode layer, and a bridge structure. As shown in FIG. 11A, the bridge structure may be in direct contact with the piezoelectric layer 1, which has the advantage that a preparation process flow of a micro-electromechanical system (MEMS) can be simplified and easy to implement. As shown in FIG. 11B, the bridge structure may be indirectly connected to the piezoelectric layer 1 by being in contact with the electrode layer instead of being in contact with the piezoelectric layer 1, which has the advantage of a good suppression effect on the pseudo mode.

### Comparison Example 1

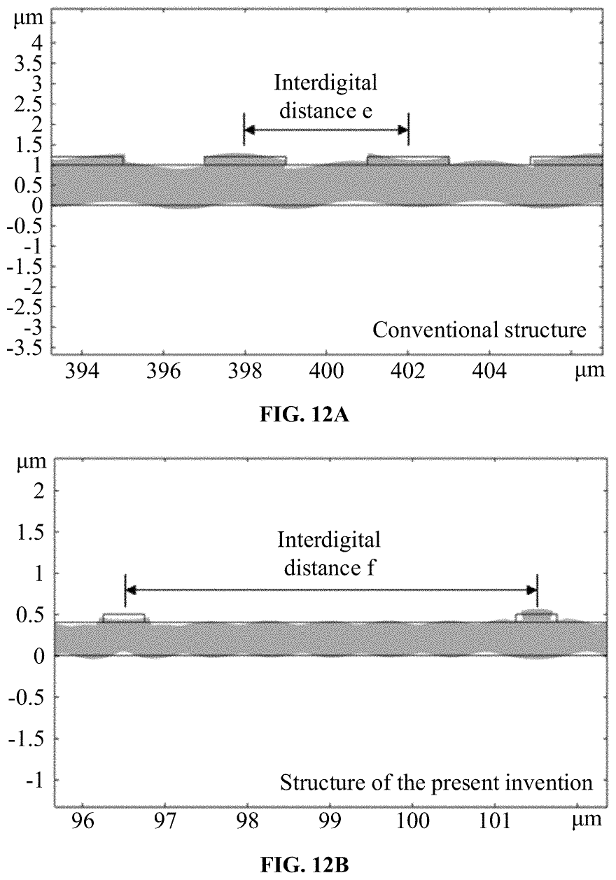

FIGS. 12A-12B are the amplitude diagrams of a conventional Lamb wave resonator structure and an amplitude diagram of the structure of the disclosure. An interdigital distance e of the conventional Lamb wave resonator structure is about one half wavelength, and an interdigital distance f of the resonator structure of the disclosure, that is, the distance between the first electrode 3 and the second electrode 4 that are adjacent and distributed in the x-axis direction, is four wavelengths or more.

### Comparison Example 2

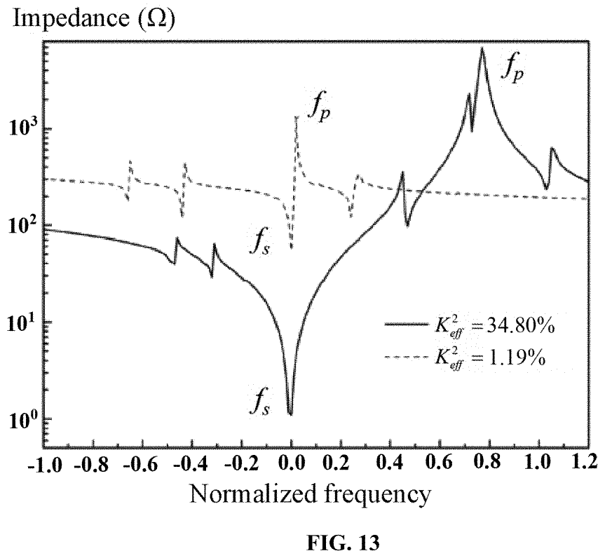

FIG. 13 is a schematic diagram of an impedance curve of the two-dimensional resonator with hexagonal electrodes according to Embodiment 2 of the disclosure and an impedance curve of a conventional Lamb wave resonator. A frequency interval Δf between a series resonance frequency fₛ and a parallel resonance frequency fₚ determines a magnitude of an electromechanical coupling coefficient K_{eff}² of the resonator, which may be calculated by using the following formula:

$${K}_{e f f}^{2} = \frac{{π}^{2}}{4} \frac{{f}_{p} - {f}_{s}}{{f}_{p}}$$

After positive and negative voltages are alternately applied to the electrode layer on the upper surface of the piezoelectric layer 1, multi-directional electric field coupling is generated inside the piezoelectric layer 1. The arrangement of the electrode layer 2 according to this embodiment of the disclosure couples e₁₅ and e₂₄ inside the piezoelectric layer 1, which is calculated by a classic piezoelectric equation:

$$\{ \begin{matrix}T = c S - e E \\ D = ε E + e S\end{matrix} where e = [ \begin{matrix}0 & 0 & 0 & 0 & {e}_{15} & - {e}_{22} \\ - {e}_{22} & {e}_{22} & 0 & {e}_{24} & 0 & 0 \\ {e}_{31} & {e}_{31} & {e}_{33} & 0 & 0 & 0\end{matrix} ] = [ \begin{matrix}0 & 0 & 0 & 0 & 3.65 & - 2.39 \\ - 2.39 & 2.39 & 0 & 3.65 & 0 & 0 \\ 0.31 & 0.31 & 1.72 & 0 & 0 & 0\end{matrix} ] ( C / {m}^{2} )$$

the coupling of e₁₅ and e₂₄ sharply increases the electric field of the structure, and improves the electromechanical coupling coefficient of the resonator.

As shown in FIG. 13, a dashed line is an impedance curve graph of a conventional Lamb wave resonator based on an AlN piezoelectric material, and a black curve is an impedance curve graph of a two-dimensional resonator structure with circular electrodes according to Embodiment 2 of the disclosure. At the same normalized resonance frequency, the electromechanical coupling coefficient K_{eff}² of the conventional Lamb wave resonator is 1.19%, and the electromechanical coupling coefficient K_{eff}² of the two-dimensional resonator with the circular electrodes according to Embodiment 2 of the disclosure is 34.80% The structure of the disclosure can greatly improve the effective electromechanical coupling coefficient of the resonator and enhance the performance of the resonator.

### Comparison Example 3

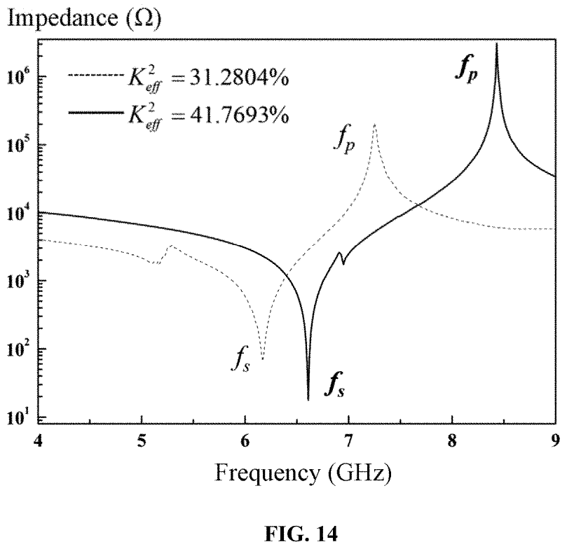

FIG. 14 is a schematic diagram of an impedance curve of the two-dimensional resonator with elliptical electrodes according to Embodiment 3 of the disclosure and an impedance curve of the two-dimensional resonator with circular electrodes according to Embodiment 1 of the disclosure. A calculation method is consistent with the calculation method in Comparison example 2. As shown in FIG. 14, the electromechanical coupling coefficient K_{eff}² of the two-dimensional resonator with the circular electrodes according to Embodiment 1 of the disclosure is 31.2804%, while the electromechanical coupling coefficient K_{eff}² of the two-dimensional resonator with the elliptical electrodes according to Embodiment 3 of the disclosure is 41.7693%, showing an increase of 33.5319%. A quality factor (Q) may be calculated by using a 3 dB bandwidth method. The quality factor (Q) of the two-dimensional resonator with the circular electrodes according to Embodiment 1 of the disclosure is 1488, and the quality factor (Q) of the two-dimensional resonator with the elliptical electrodes according to Embodiment 3 of the disclosure is 1029, showing an increase of 44.6064%. Therefore, the structure of this embodiment can greatly improve the effective electromechanical coupling coefficient and the quality factor of the resonator and enhance the performance of the resonator. The resonance frequency is greater than 6 GHz, and an advantageous hardware foundation is laid for the development of the next generation ultra-5G technology.

### Comparison Example 4

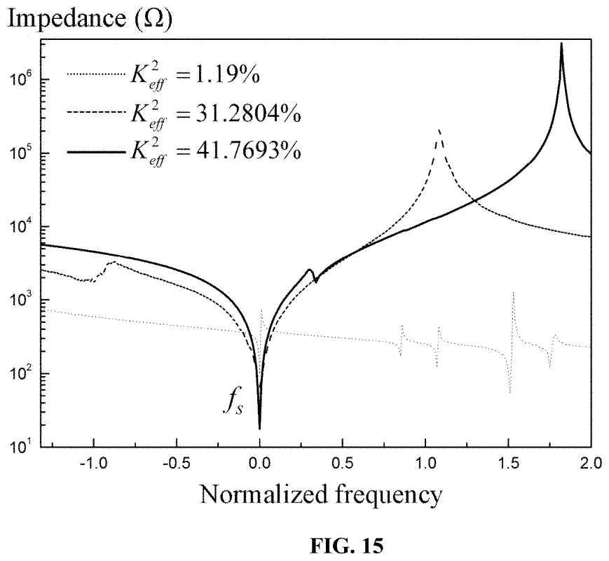

FIG. 15 is a schematic diagram of an impedance curve of the two-dimensional resonator with elliptical electrodes according to Embodiment 3 of the disclosure, an impedance curve of the two-dimensional resonator with circular electrodes according to Embodiment 1 of the disclosure, and an impedance curve of a conventional Lamb wave resonator. A calculation method is consistent with the calculation method in Comparison example 2. As shown in FIG. 15, the electromechanical coupling coefficient K_{eff}² of the conventional Lamb wave resonator is 1.19%, and the electromechanical coupling coefficient K_{eff}² of the two-dimensional resonator with the circular electrodes according to Embodiment 1 of the disclosure is 31.2804%, while the electromechanical coupling coefficient K_{eff}² of the two-dimensional resonator with the elliptical electrodes according to Embodiment 3 of the disclosure is 41.7693%. Therefore, the performance of the two-dimensional resonator in the disclosure is obviously superior to that of the conventional Lamb wave resonator.

The embodiments of the disclosure are described above with reference to the accompanying drawings. However, the disclosure is not limited to the foregoing specific implementations, and the foregoing specific implementations are merely exemplary, but not limited. A plurality of forms may be further made by a person of ordinary skill in the art in enlightenment of the disclosure without depart from the purpose of the disclosure and the protection scope of the claims and all fall within the protection scope of the disclosure.

What is claimed is:

1. A two-dimensional resonator, comprising a piezoelectric layer, wherein an electrode layer is distributed on an upper surface of the piezoelectric layer; the electrode layer comprises a plurality of electrodes arranged in a horizontal direction with respect to xy-plane with a distance therebetween greater than four wavelengths, and a bridge structure is arranged on an upper portion of the electrode layer.

2. The two-dimensional resonator of claim 1, wherein the bridge structure is in direct contact with the piezoelectric layer and connects electrodes that are adjacent in a vertical direction.

3. The two-dimensional resonator of claim 1, wherein the bridge structure is in indirect contact with the piezoelectric layer and connects electrodes that are adjacent in a vertical direction with respect to xy-plane.

4. The two-dimensional resonator of claim 1, wherein a shape of the bridge structure is a rectangle, a quadrangle, or a polygon.

5. The two-dimensional resonator of claim 4, wherein a material of the bridge structure is selected from platinum, molybdenum, gold, tungsten, copper, or aluminum.

6. The two-dimensional resonator of claim 1, wherein a material of the piezoelectric layer is selected from lithium niobate, lithium tantalate, aluminum nitride, or doped aluminum nitride. The two-dimensional resonator of claim 1, wherein a material of the electrodes is selected from platinum, molybdenum, gold, tungsten, copper, or aluminum.

8. The two-dimensional resonator of claim 1, wherein the electrode layer comprises a plurality of electrodes arranged in a vertical direction with respect to xy-plane with a distance therebetween less than and equal to four wavelengths.

9. The two-dimensional resonator of claim 7, wherein the electrode layer comprises a plurality of electrodes arranged in a vertical direction with respect to xy-plane with a distance therebetween less than and equal to four wavelengths.

10. The two-dimensional resonator of claim 1, wherein a shape of the electrodes is an ellipse, a circle, a rectangle, a rhombus, a hexagon, an octagon, a polygon, or a combination of different shapes.

11. The two-dimensional resonator of claim 7, wherein a shape of the electrodes is an ellipse, a circle, a rectangle, a rhombus, a hexagon, an octagon, a polygon, or a combination of different shapes.

12. The two-dimensional resonator of claim 10, wherein the shape of the electrode is an ellipse, the distance between adjacent electrodes distributed in the horizontal direction is greater than four wavelengths, and the distance between adjacent electrodes distributed in the vertical direction is less than four wavelengths and twice a major axis of the ellipse.

13. The two-dimensional resonator of claim 11, wherein the shape of the electrode is an ellipse, the distance between adjacent electrodes distributed in the horizontal direction is greater than four wavelengths, and the distance between adjacent electrodes distributed in the vertical direction is less than four wavelengths and twice a major axis of the ellipse.

14. The two-dimensional resonator of claim 10, wherein the shape of the electrode is an ellipse, the distance between adjacent electrodes distributed in the horizontal direction is greater than four wavelengths, and the distance between adjacent electrodes distributed in the vertical direction is less than four wavelengths and greater than twice a major axis of the ellipse.

15. The two-dimensional resonator of claim 11, wherein the shape of the electrode is an ellipse, the distance between adjacent electrodes distributed in the horizontal direction is greater than four wavelengths, and the distance between adjacent electrodes distributed in the vertical direction is less than four wavelengths and greater than twice a major axis of the ellipse.

16. The two-dimensional resonator of claim 1, wherein the two-dimensional electrode arrangement of the two-dimensional resonator enables an electric field in the horizontal direction and a vertical direction to generate a coupling effect, and coupling of multi-directional electric fields increases an electromechanical coupling coefficient of the resonator.
